(19) United States
(12) Patent Application Publication
(10) Pub. No.: US 2026/0144129 A1
(43) Pub. Date: May 21, 2026

(54) SEMICONDUCTOR PACKAGE AND METHOD OF MANUFACTURING THE SAME

(71) Applicant: Samsung Electronics Co., Ltd., Suwon-si (KR)

(72) Inventors: Hyoeun Kim, Suwon-si (KR); Chajea Jo, Suwon-si (KR); Dohyun Kim, Suwon-si (KR); Huiyeong Jang, Suwon-si (KR)

(21) Appl. No.: 19/249,069

(22) Filed: Jun. 25, 2025

(30) Foreign Application Priority Data
Nov. 19, 2024 (KR) 10-2024-0165608

(51) Int. Cl. H01L 23/31; H01L 21/56; H01L 23/00; H01L 23/29; H01L 23/373; H01L 23/48; H01L 25/00; H01L 25/18; H10B 80/00; H10D 80/30

(52) U.S. Cl. CPC H10W 74/121; H10B 80/00; H10D 80/30; H10W 40/251; H10W 74/01; H10W 74/473; H10W 90/00; H10W 20/20; H10W 72/072; H10W 72/07232; H10W 72/073; H10W 72/07332; H10W 72/241; H10W 74/15; H10W 80/312; H10W 80/327; H10W 90/20; H10W 90/22; H10W 90/297; H10W 90/722; H10W 90/732; H10W 90/792

(57) ABSTRACT

Aspects of the technical idea of the inventive concept provide a semiconductor package including a semiconductor package module, a semiconductor device provided below the semiconductor package module, a redistribution layer between the semiconductor package module and the semiconductor device, and an encapsulation material surrounding the semiconductor package module, on the redistribution layer, wherein the semiconductor package module includes a base chip, a plurality of memory chips disposed on the base chip, and a sealing material sealing the plurality of memory chips on the base chip, each of the plurality of memory chips includes a first semiconductor substrate, a first active layer on a lower surface of the first semiconductor substrate, and a first through electrode extending through the first semiconductor substrate.

### CROSS-REFERENCE TO RELATED APPLICATION

This application is based on and claims priority under 35 U.S.C. § 119 to Korean Patent Application No. 10-2024-0165608, filed on Nov. 19, 2024, in the Korean Intellectual Property Office, the disclosure of which is incorporated by reference herein in its entirety.

### BACKGROUND

The inventive concept relates to a semiconductor package and a method of manufacturing the same, and more particularly, to a semiconductor package including a plurality of semiconductor chips that are stacked and a method of manufacturing the same.

Along with the rapid development of the electronics industry and demands of users, electronic devices have become increasingly miniaturized and more lightweight. In accordance with the miniaturization and weight reduction of electronic devices, semiconductor packages used therein also have been increasingly miniaturized and more lightweight, and in addition, there is demand for semiconductor packages having high performance, large capacity, and high reliability. To implement miniaturization, weight reduction, high performance, large capacity, and high reliability, research and development of semiconductor chips including a through silicon via (TSV) structure and semiconductor packages of a chip-stacked structure in which such semiconductor chips are stacked are continuously being conducted.

### SUMMARY

Aspects of the inventive concept provide a semiconductor package including a plurality of semiconductor chips that are stacked, thereby efficiently manufacturing a customized semiconductor package and providing a customized semiconductor package satisfying particular requirements of a consumer.

In addition, issues addressed by the technical idea of the inventive concept are not limited to the issues mentioned above, and other addressed issues could be clearly understood by those of ordinary skill in the art from the description below.

According to an aspect of the inventive concept, there is provided a semiconductor package including a semiconductor package module, a semiconductor device provided below the semiconductor package module, a redistribution layer between the semiconductor package module and the semiconductor device, and an encapsulation material surrounding the semiconductor package module, on the redistribution layer, wherein the semiconductor package module includes a base chip, a plurality of memory chips disposed on the base chip, and a sealing material sealing the plurality of memory chips on the base chip, each of the plurality of memory chips includes a first semiconductor substrate, a first active layer on a lower surface of the first semiconductor substrate, and a first through electrode extending through the first semiconductor substrate, the base chip includes a second semiconductor substrate, a second active layer on a lower surface of the second semiconductor substrate, and a second through electrode extending through the second semiconductor substrate, the semiconductor device includes a third semiconductor substrate, a third active layer on a lower surface of the third semiconductor substrate, and a third through electrode extending through the third semiconductor substrate, and the redistribution layer is formed on an upper surface of the third semiconductor substrate.

According to another aspect of the inventive concept, there is provided a semiconductor package including a semiconductor package module, a semiconductor device provided beneath the semiconductor package module, a redistribution layer provided beneath the semiconductor device, and an encapsulation material surrounding the semiconductor package module, on the semiconductor device, wherein the semiconductor package module includes a base chip, a plurality of memory chips disposed on the base chip, and a sealing material sealing the plurality of memory chips on the base chip, each of the plurality of memory chips includes a first semiconductor substrate, a first active layer on a lower surface of the first semiconductor substrate, and a first through electrode extending through the first semiconductor substrate, the base chip includes a second semiconductor substrate, a second active layer on a lower surface of the second semiconductor substrate, and a second through electrode extending the second semiconductor substrate, the semiconductor device includes a third semiconductor substrate, a third active layer on an upper surface of the third semiconductor substrate, and a third through electrode extending through the third semiconductor substrate, and the redistribution layer is formed on a lower surface of the third semiconductor substrate.

According to another aspect of the inventive concept, there is provided a method of manufacturing a semiconductor package, the method including forming a plurality of base chips on a first wafer, stacking a plurality of memory chips on each of the plurality of base chips provided on the first wafer, forming a sealing material surrounding the plurality of memory chips, on the first wafer, individualizing the first wafer on which the plurality of memory chips are stacked, into a plurality of semiconductor package modules, mounting a semiconductor package module on a semiconductor device, and forming an encapsulation material surrounding the semiconductor package module, on the semiconductor device, wherein the plurality of memory chips, the base chip, and the semiconductor device have a plurality of first through electrodes, a plurality of second through electrodes, and a plurality of third through electrodes, respectively.

### BRIEF DESCRIPTION OF THE DRAWINGS

Embodiments of the inventive concept will be more clearly understood from the following detailed description taken in conjunction with the accompanying drawings in which:

FIG. 1 is a cross-sectional view schematically illustrating a semiconductor package according to an embodiment;

FIG. 2 is a cross-sectional view schematically illustrating a semiconductor package according to another embodiment;

FIG. 3 is a cross-sectional view schematically illustrating a semiconductor package according to another embodiment;

FIG. 4 is a cross-sectional view schematically illustrating a semiconductor package according to another embodiment;

FIG. 5 is a cross-sectional view schematically illustrating a semiconductor package according to another embodiment;

FIG. 6 is a cross-sectional view schematically illustrating a semiconductor package according to another embodiment;

FIG. 7 is a cross-sectional view schematically illustrating a semiconductor package according to another embodiment;

FIG. 8 is a cross-sectional view schematically illustrating a semiconductor package according to another embodiment;

FIGS. 9A to 9E are cross-sectional views sequentially illustrating a method of manufacturing a semiconductor package module, according to an embodiment; and

FIGS. 10A and 10B are cross-sectional views sequentially illustrating a method of manufacturing a semiconductor package, according to an embodiment.

### DETAILED DESCRIPTION OF THE EMBODIMENTS

Hereinafter, embodiments are described in detail with reference to the accompanying drawings. The inventive concept may, however, be embodied in many different forms and should not be construed as being limited to the embodiments set forth herein. Rather, these embodiments are provided so that this disclosure will be thorough and complete, and will fully convey the scope of the inventive concept to those of ordinary skill in the art.

Throughout the specification, when a component is described as “including” a particular element or group of elements, it is to be understood that the component is formed of only the element or the group of elements, or the element or group of elements may be combined with additional elements to form the component, unless the context clearly and/or explicitly describes the contrary.

Ordinal numbers such as “first,” “second,” “third,” etc. may be used simply as labels of certain elements, steps, etc., to distinguish such elements, steps, etc. from one another. Terms that are not described using “first,” “second,” etc., in the specification, may still be referred to as “first” or “second” in a claim. In addition, a term that is referenced with a particular ordinal number (e.g., “first” in a particular claim) may be described elsewhere with a different ordinal number (e.g., “second” in the specification or another claim).

As used herein, components described as being “electrically connected” are configured such that an electrical signal can be transferred from one component to the other (although such electrical signal may be attenuated in strength as it is transferred and may be selectively transferred).

Spatially relative terms, such as “beneath,” “below,” “lower,” “above,” “upper,” “top,” “bottom,” “front,” “rear,” and the like, may be used herein for ease of description to describe positional relationships, such as illustrated in the figures, for example. It will be understood that the spatially relative terms encompass different orientations of the device in addition to the orientation depicted in the figures.

It will be understood that when an element is referred to as being “connected” or “coupled” to or “on” another element, it can be directly connected or coupled to or on the other element or intervening elements may be present. In contrast, when an element is referred to as being “directly connected,” “directly attached,” “directly joined,” or “directly coupled” to another element, or as “contacting” or “in contact with” another element (or using any form of the word “contact”), there are no intervening elements present at the point of contact.

Various pads of a device described herein may be conductive terminals connected to internal wiring of the device, and may transmit signals and/or supply voltages between an internal wiring and/or internal circuit of the device and an external source. For example, chip pads of a semiconductor chip may electrically connect to and transmit supply voltages and/or signals between an integrated circuit of the semiconductor chip and a device to which the semiconductor chip is connected. The various pads may be provided on or near an external surface of the device and may have a planar surface having dimensions greater than wiring (e.g., X-Y horizontal dimensions of a pad are both greater than the width of an internal writing to which it is connected) to promote an electrical connection to a further terminal, such as a bump or solder ball, and/or an external wiring.

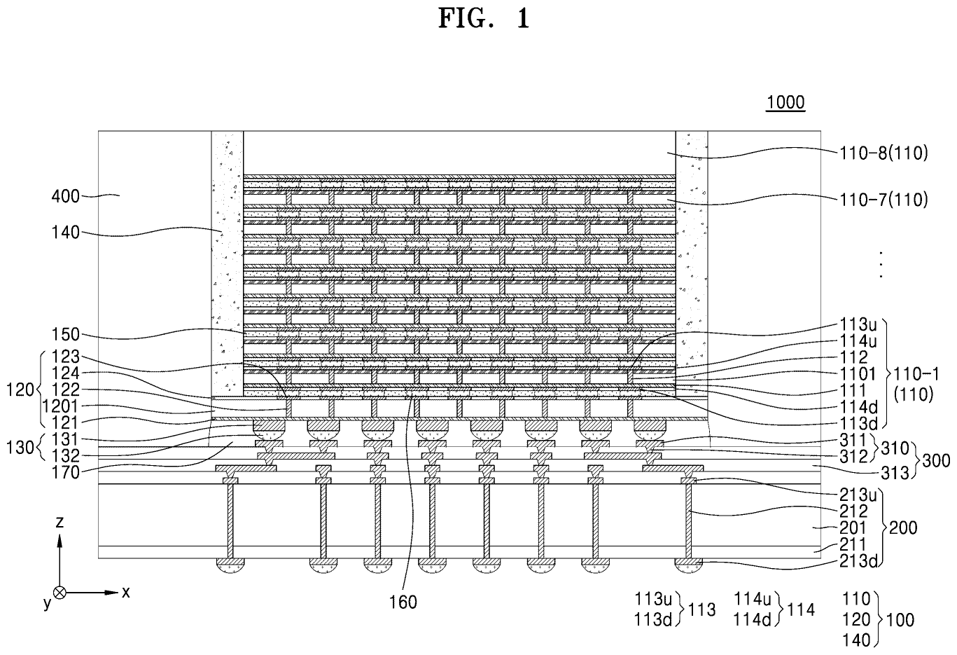

FIG. 1 is a cross-sectional view schematically illustrating a semiconductor package 1000 according to an embodiment.

Referring to FIG. 1, the semiconductor package 1000 according to an embodiment may include a semiconductor package module 100, a semiconductor device 200, a redistribution layer 300, and an encapsulation material 400.

The semiconductor package module 100 may include, for example, a plurality of memory chips 110 that are stacked, a base chip 120, and a sealing material 140.

A memory chip 110 may include a semiconductor substrate 1101, an active layer 111, a through electrode 112, a connection pad 113, a protective layer 114, and a connection terminal 160.

The semiconductor substrate 1101 may constitute a body of the memory chip 110 and include silicon (Si). However, the material of the semiconductor substrate 1101 is not limited to Si. For example, the semiconductor substrate 1101 may include another semiconductor material, such as germanium (Ge) or silicon germanium (SiGe), or a compound semiconductor, such as silicon carbide (SiC), gallium phosphide (GaP), gallium arsenide (GaAs), gallium antimonide (GaSb), or indium phosphide (InP). In some embodiments, the semiconductor substrate 1101 may include or may be a silicon-on-insulator (SOI) substrate or a germanium-on-insulator (GOI) substrate. For example, the semiconductor substrate 1101 may include a buried oxide (BOX) layer.

The active layer 111 may be provided under the semiconductor substrate 1101 and include an integrated circuit layer and a wiring layer. For example, the integrated circuit layer may include various active devices and/or passive devices, such as a transistor, logic devices, memory devices, a system large scale integration (LSI) chip, a complementary metal-insulator-semiconductor (CMOS) imaging sensor (CIS), and a micro-electro-mechanical system (MEMS).

The transistor may include or may be, for example, a field effect transistor (FET), such as a bipolar junction transistor (BJT), a planar FET, or a FinFET. The logic devices may include, for example, AND, NAND, OR, NOR, exclusive OR (XOR), exclusive NOR (XNOR), inverter (INV), adder (ADD), delay (DLY), filter (FIL), multiplexer (MXT/MXIT), OR/AND/INV (OAI), AND/OR (AO), AND/OR/INV (AOI), D flip-flop, reset flip-flop, master-slaver flip-flop, latch, counter, and buffer devices. The logic devices may perform various kinds of signal processing, such as analog signal processing, analog-to-digital (A/D) conversion, and control.

The memory devices may include, for example, flash memory, dynamic random access memory (DRAM) or static random access memory (SRAM), electrically erasable programmable read-only memory (EEPROM), phase-change random access memory (PRAM), magnetoresistive random access memory (MRAM), ferroelectric random access memory (FeRAM), resistive random access memory (RRAM), and the like.

In the memory chip 110 of the present embodiment, the integrated circuit layer of the active layer 111 may include a plurality of memory devices. For example, the integrated circuit layer may include volatile memory devices, such as DRAM and SRAM, or non-volatile memory devices, such as PRAM, MRAM, FeRAM, and RRAM. In the memory chip 110 of the present embodiment, the integrated circuit layer of the active layer 111 may include DRAM devices. Accordingly, the memory chip 110 may be a DRAM chip. Alternatively, the memory chip 110 may be a DRAM chip for high bandwidth memory (HBM). However, the memory chip 110 of the present embodiment is not limited to the DRAM chip or the DRAM chip for HBM.

The wiring layer of the active layer 111 may be provided under the integrated circuit layer. The wiring layer may electrically connect devices to each other or electrically connect the devices to the connection terminal 160. In addition, the wiring layer may electrically connect the through electrode 112 to the connection terminal 160. The wiring layer may include an interlayer insulating layer and wirings. The wirings may be electrically connected to the devices of the integrated circuit layer, the through electrode 112, or the connection terminal 160 via a contact or a via. The wirings may be provided as two or more layers of wirings. Wirings in different layers may be isolated by the interlayer insulating layer and electrically connected to each other via the via.

The through electrode 112 may extend in the vertical direction, i.e., the z direction, by passing through the semiconductor substrate 1101. In some embodiments, the through electrode 112 may extend into the active layer 111. When the semiconductor substrate 1101 includes Si, the through electrode 112 may correspond to or may be a through silicon via (TSV). As a reference, the through electrode 112 may be classified into a via-first structure formed before the integrated circuit layer is formed, a via-middle structure formed after the integrated circuit layer is formed and before the wiring layer is formed, and a via-last structure formed after the wiring layer is formed. The memory chip 110 of the present embodiment may include, for example, the through electrode 112 of the via-middle structure. However, the memory chip 110 of the present embodiment is not limited thereto and may include the through electrode 112 of the via-first or via-last structure.

For example, the through electrode 112 may have a pillar shape extending in the z direction and include an electrode layer, and an electrode insulating layer may surround the electrode layer. The electrode layer may include a barrier film on the outer surface thereof and a buried conductive layer therein. The barrier film may include at least one material selected from among titanium (Ti), titanium nitride (TiN), tantalum (Ta), tantalum nitride (TaN), ruthenium (Ru), cobalt (Co), manganese (Mn), tungsten nitride (WN), nickel (Ni), and nickel boron (NiB). The buried conductive layer may include at least one material selected from among copper (Cu), Cu alloys, such as copper tin (CuSn), copper magnesium (CuMg), copper nickel (CuNi), copper zinc (CuZn), copper palladium (CuPd), copper gold (CuAu), copper rhenium (CuRe), and copper tungsten (CuW), tungsten (W), W alloys, Ni, Ru, and Co. However, the materials of the barrier film and the buried conductive layer are not limited to the materials described above.

The electrode insulating layer may have a structure surrounding the outer side surface of the electrode layer. Accordingly, the electrode insulating layer may be provided between the electrode layer and the semiconductor substrate 1101 and/or between the electrode layer and the active layer 111, e.g., when the electrode layer and the electrode insulating layer pass through the active layer 111. The electrode insulating layer may include, for example, an oxide film, a nitride film, a carbide film, a polymer, or a combination thereof. In the memory chip 110 of the present embodiment, the electrode insulating layer may include, for example, silicon oxide (SiO₂). However, the material of the electrode insulating layer is not limited to SiO₂.

The connection pad 113 may include an upper connection pad 113u and a lower connection pad 113d. The upper connection pad 113u may be disposed on the upper surface of the memory chip 110. As shown in FIG. 1, the upper connection pad 113u may be directly connected to or contact the through electrode 112. The lower connection pad 113d may be disposed on the lower surface of the memory chip 110. The lower connection pad 113d may be electrically connected to the through electrode 112 via the wiring layer. The connection pad 113 may include at least one of, for example, aluminum (Al), Cu, Ni, W, platinum (Pt), and gold (Au). In the memory chip 110 of the present embodiment, the connection pad 113 may include Cu. However, the material of the connection pad 113 is not limited to Cu.

The protective layer 114 may be disposed on the lower surface and the upper surface of the memory chip 110. The protective layer 114 may include a lower protective layer 114d on the lower surface of the memory chip 110 and an upper protective layer 114u on the upper surface of the memory chip 110. In the memory chip 110 of the present embodiment, each of the lower protective layer 114d and the upper protective layer 114u may have a multi-layer structure. For example, each of the lower protective layer 114d and the upper protective layer 114u may include two or more insulating layers. However, the number of layers of each of the lower protective layer 114d and the upper protective layer 114u is not limited to the numerical value range described above. For convenience, FIG. 1 shows that each of the lower protective layer 114d and the upper protective layer 114u has a single layer. The protective layer 114 may include, for example, an oxide film, a nitride film, a carbide film, a polymer, or a combination thereof.

In the memory chip 110 of the present embodiment, a lower surface may be a front side (FS) that is an active surface, and an upper surface may be a back side (BS) that is an inactive surface. For example, the lower surface of the wiring layer of the active layer 111 may correspond to or be the FS of the memory chip 110, and the upper surface of the semiconductor substrate 1101 may correspond to or be the BS of the memory chip 110. Therefore, the lower protective layer 114d and the lower connection pad 113d may be disposed on the FS that is the active surface of the memory chip 110, and the upper protective layer 114u and the upper connection pad 113u may be disposed on the BS that is the inactive surface of the memory chip 110.

The lower connection pad 113d may have a structure passing through at least a portion of the lower protective layer 114d, e.g., in a vertical direction. For example, the lower connection pad 113d may have a structure fully or partially passing through the lower protective layer 114d, e.g., in the vertical direction. The lower connection pad 113d may have a structure buried in the lower protective layer 114d and be exposed from the lower surface of the lower protective layer 114d. The lower connection pad 113d may be electrically connected to and/or contact the wirings of the wiring layer of the active layer 111. In addition, the lower connection pad 113d may be electrically connected to the through electrode 112 via the wiring layer of the wiring layer.

The upper connection pad 113u may have a structure passing through at least a portion of the upper protective layer 114u, e.g., in the vertical direction. For example, the upper connection pad 113u may have a structure fully or partially passing through the upper protective layer 114u, e.g., in the vertical direction. The upper connection pad 113u may have a structure buried in the upper protective layer 114u and be exposed from the upper surface of the upper protective layer 114u. The upper connection pad 113u may be directly connected to the through electrode 112. For example, the lower surface of the upper connection pad 113u may be in contact with the upper surface of the through electrode 112.

The connection terminal 160 may be disposed on the lower surface of the memory chip 110. For example, the connection terminal 160 may be disposed on the lower connection pad 113d on the lower surface of the memory chip 110. The connection terminal 160 may include a solder. The solder may include tin (Sn), indium (In), bismuth (Bi), antimony (Sb), Cu, silver (Ag), zinc (Zn), and/or an alloy thereof. For example, the solder may include Sn, Sn—Ag, Sn—Au, Sn—Cu, Sn—Bi, Sn—Zn, Sn—Ag—Cu, Sn—Ag—Bi, Sn—Ag—Zn, Sn—Cu—Bi, Sn—Cu—Zn, Sn—Bi—Zn, or the like. In some embodiments, the connection terminal 160 may be a bump, a solder, a solder bump, or the like.

In some embodiments, the connection terminal 160 may further include a pillar, and the solder may be disposed on the pillar. The pillar may include, for example, Ni, Cu, palladium (Pd), Pt, Au, or a combination thereof. In some embodiments, the pillar may function as a chip pad and include Cu. In this case, the pillar may be a bump pad, a Cu pad, a Cu pillar, or the like. When the pillar functions as a chip pad, an additional chip pad, e.g., the lower connection pad 113d, on the lower surface of the memory chip 110 may not be formed on the pillar.

The plurality of memory chips 110 may be stacked on the base chip 120. In the semiconductor package 1000 of the present embodiment, eight memory chips 110, e.g., first to eighth memory chips 110-1 to 110-8, may be stacked on the base chip 120. However, the number of memory chips 110 stacked on the base chip 120 is not limited to 8. For example, the number of memory chips 110 stacked on the base chip 120 may be 2 to 7, 9, or more.

As a reference, in the semiconductor package module 100 of the present embodiment, the number of memory chips 110 may be 4n (n is a natural number). Accordingly, the semiconductor package module 100 may include a multiple of four memory chips 110, such as four, eight, or twelve memory chips 110. In addition, every four memory chips 110 may be tested and operated together with the same stack identification (ID). For example, when the semiconductor package module 100 includes eight memory chips 110, the first to fourth memory chips 110-1 to 110-4 may have a first stack ID, and the fifth to eighth memory chips 110-5 to 110-8 may have a second stack ID. However, the semiconductor package module 100 of the present embodiment is not limited to a multiple of four memory chips 110 and stack IDs corresponding thereto. For example, the semiconductor package module 100 of the present embodiment may include a multiple of two memory chips 110 and stack IDs corresponding thereto or include a multiple of eight memory chips 110 and stack IDs corresponding thereto.

The first to eighth memory chips 110-1 to 110-8 may have the same horizontal size (e.g., the same plan view area) and internal structure. However, the eighth memory chip 110-8 that is the uppermost memory chip 110-8 may not include a through electrode. In addition, as shown in FIG. 1, the eighth memory chip 110-8 may be thicker than each of the other memory chips 110. In some embodiments, the total height of the semiconductor package module 100 may be adjusted by adjusting the thickness of the eighth memory chip 110-8.

In the semiconductor package module 100 of the present embodiment, the first to eighth memory chips 110-1 to 110-8 may be stacked on the base chip 120 or an immediately lower memory chip 110 through connection terminals 160. For example, each of the connection terminals 160 may be provided between a connection pad 123 of the base chip 120 and a lower connection pad 113d of the first memory chip 110-1 or between an upper connection pad 113u of a lower memory chip 110 and a lower connection pad 113d of an upper memory chip 110.

In the semiconductor package module 100 of the present embodiment, because the first to eighth memory chips 110-1 to 110-8 are stacked through the connection terminals 160, an adhesive layer 150 may be provided between the base chip 100 and the first memory chip 110-1 and between every pair of adjacent memory chips 110. For example, the adhesive layer 150 may fill between the base chip 120 and the first memory chip 110-1 and between every pair of adjacent memory chips 110 and cover/contact the side surfaces of the connection terminals 160. In addition, as a modified example, the adhesive layer 150 may protrude laterally from and cover side surfaces of the first to eighth memory chips 110-1 to 110-8. In some embodiments, the adhesive layer 150 may laterally protrude from the side surfaces of the first to eighth memory chips 110-1 to 110-8 but cover only a portion of the side surface of each of the first to eighth memory chips 110-1 to 110-8. In this case, on the side surface of each of the first to eighth memory chips 110-1 to 110-8, a lower-side adhesive layer 150 may be separated from an upper-side adhesive layer 150 without adhering to each other.

The adhesive layer 150 may include, for example, a non-conductive film (NCF). The NCF may be used as, for example, an adhesive layer when semiconductor chips are bonded to each other by thermal compression bonding (TCB) in a semiconductor chip stacking process. However, the material of the adhesive layer 150 is not limited to the NCF.

In the semiconductor package module 100 of the present embodiment, each of the first to eighth memory chips 110-1 to 110-8 may include or may be a DRAM chip. Alternatively, each of the first to eighth memory chips 110-1 to 110-8 may include or may be a DRAM for HBM. Accordingly, the semiconductor package module 100 of the present embodiment may be an HBM package. However, the semiconductor package module 100 of the present embodiment is not limited to the HBM package.

The base chip 120 may be disposed beneath the first to eighth memory chips 110-1 to 110-8. As shown in FIG. 1, the base chip 120 may have a larger size than the first to eighth memory chips 110-1 to 110-8 disposed thereon, e.g., in a plan view and/or in a lateral view. However, the size of the base chip 120 is not limited thereto. For example, in some embodiments, the base chip 120 may have the same or substantially the same size as the first to eighth memory chips 110-1 to 110-8, e.g., in the plan view and/or in the lateral view.

The base chip 120 may include a semiconductor substrate 1201, an active layer 121, a through electrode 122, the connection pad 123, and a protective layer 124. The semiconductor substrate 1201, the active layer 121, the through electrode 122, the connection pad 123, and the protective layer 124 may be the same as described above with respect to the semiconductor substrate 1101, the active layer 111, the through electrode 112, the connection pad 113, and the protective layer 114 of the memory chip 110 of FIG. 1.

However, the base chip 120 may include a plurality of logic devices in an integrated circuit layer of the active layer 121. Accordingly, the base chip 120 may be a logic chip. The base chip 120 may be disposed beneath the first to eighth memory chips 110-1 to 110-8, integrate signals from the first to eighth memory chips 110-1 to 110-8 and transmit the integrated signal to the outside, and transmit a signal and power from the outside to the first to eighth memory chips 110-1 to 110-8. Accordingly, the base chip 120 may be a buffer chip or an interface chip. As a reference, when the base chip 120 is a buffer chip or the like, each of the first to eighth memory chips 110-1 to 110-8 may be a core chip.

In some embodiments, the base chip 120 may include a controller configured to control signal transmission between the first to eighth memory chips 110-1 to 110-8 and an external device. When the base chip 120 includes the controller, the base chip 120 may be a logic chip, a control chip, or the like. In addition, in some embodiments, the base chip 120 may include a power management integrated circuit (PMIC) configured to manage power or a clock.

In the semiconductor package module 100 of the present embodiment, the base chip 120 is not limited to a buffer chip or a logic chip. For example, the base chip 120 may include a plurality of memory devices in the integrated circuit layer of the active layer 121. Accordingly, the base chip 120 may include or may be a memory chip.

In the semiconductor package module 100 shown in FIG. 1, the connection pad 123 and the protective layer 124 may correspond to the upper connection pad 113u and the upper protective layer 114u of the memory chip 110. For example, the descriptions with respect to the upper connection pad 113u and the upper protective layer 114u may be applied to the connection pad 123 and the protective layer 124 respectively unless contexts indicate otherwise. The base chip 120 may also include a lower connection pad and a lower protective layer. However, in FIG. 1 and the other drawings, because a first external connection terminal 130 is shown to be relatively large, the lower connection pad and the lower protective layer are not shown for convenience.

The first external connection terminal 130 may be disposed on the lower surface of the base chip 120. The first external connection terminal 130 may be electrically connected to and/or contact wirings of a wiring layer of the active layer 121 of the base chip 120. In addition, the first external connection terminal 130 may be electrically connected to the through electrode 122 via the wirings of the wiring layer of the active layer 121. Although not shown in FIG. 1, a chip pad may be disposed on the lower surface of the base chip 120, and the first external connection terminal 130 may be disposed on the chip pad. Herein, the chip pad may correspond to the lower connection pad 113d. For example, the descriptions with respect to the lower connection pad 113d may be applied to the chip pad unless contexts indicate otherwise.

The first external connection terminal 130 may include a pillar 131 and a solder 132. The pillar 131 may have a cylindrical shape. The material of the pillar 131 is the same as described above with respect to the pillar of the connection terminal 160. In some embodiments, the pillar 131 may function as the chip pad of the base chip 120 and include Cu. Accordingly, the pillar 131 may be a bump pad, a Cu pad, a Cu pillar, or the like. When the pillar 131 functions as a chip pad, a separate chip pad may not be formed on the lower surface of the base chip 120.

The solder 132 may be disposed on the pillar 131 and have a semi-spherical shape. The material of the solder 132 is the same as described above with respect to the solder of the connection terminal 160. In some embodiments, the solder 132 may be a bump, a solder bump, or the like. An intermediate layer may be formed in a contact interface between the pillar 131 and the solder 132. The intermediate layer may include an inter-metallic compound (IMC) formed when metal materials included in the pillar 131 and the solder 132 react at a relatively high temperature.

The sealing material 140 may seal the first to eighth memory chips 110-1 to 110-8 on the base chip 120. For example, the sealing material 140 may cover/contact the side surfaces of the first to eighth memory chips 110-1 to 110-8 on the base chip 120 and/or adhesive layers 150 protruding on the side surfaces of the first to eighth memory chips 110-1 to 110-8. As shown in FIG. 1, the sealing material 140 may not cover the upper surface of the uppermost memory chip 110-8, e.g., the eighth memory chip 110-8. Accordingly, the upper surface of the eighth memory chip 110-8 may be exposed from the sealing material 140. However, in some embodiments, the sealing material 140 may cover/contact the upper surface of the uppermost memory chip 110-8, e.g., the eighth memory chip 110-8. The sealing material 140 may include, for example, an epoxy mold compound (EMC). However, the material of the sealing material 140 is not limited to the EMC. For example, the sealing material 140 may be a sealing layer or a molding layer protecting the memory chips 110 and/or the base chip 120 from chemical, thermal, and mechanical stress.

The semiconductor device 200 may be disposed below the semiconductor package module 100 and electrically connected to the semiconductor package module 100 by the redistribution layer 300 interposed between the semiconductor device 200 and the semiconductor package module 100. For example, the redistribution layer 300 and the semiconductor package module 100 may be stacked on the semiconductor device 200.

An under-fill layer 170 may be provided between the semiconductor package module 100 and the redistribution layer 300 by capillary under-fill (CUF) performed after the semiconductor package module 100 is bonded onto the redistribution layer 300.

The semiconductor device 200 may include, for example, a semiconductor substrate 201, an active layer 211, a through electrode 212, and connection pads 213u and 213d. The semiconductor substrate 201, the active layer 211, the through electrode 212, and the connection pads 213u and 213d of the semiconductor device 200 may be the same as described above with respect to the semiconductor substrate 1101, the active layer 111, the through electrode 112, and the connection pad 113 of the memory chip 110 of FIG. 1.

The semiconductor device 200 may have a chip structure. The semiconductor device 200 may include a plurality of logic devices in the active layer 211. The plurality of logic devices may include, for example, AND, NAND, OR, NOR, XOR, XNOR, INV, ADD, DLY, FIL, MXT/MXIT, OAI, AO, AOI, D flip-flop, reset flip-flop, master-slaver flip-flop, latch, counter, and buffer devices. The plurality of logic devices may perform various kinds of signal processing, such as analog signal processing, A/D conversion, and control. The semiconductor device 200 may be a central processing unit (CPU) chip, a system on glass (SOG) chip, a micro-processor unit (MPU) chip, a graphics processing unit (GPU) chip, a neural processing unit (NPU) chip, an application processor (AP) chip, a control chip, or the like according to the function thereof.

In the semiconductor package 1000 of the present embodiment, the semiconductor device 200 has a chip structure, wherein the chip structure may be a system on chip (SoC) structure or a chiplet structure. The SoC structure may have a structure in which a plurality of systems are integrated in a single chip. Accordingly, the semiconductor device 200 of the SoC structure may perform computation function, data storage, analog and digital signal conversion, and the like in a single chip. The chiplet structure may have a structure in which a logic chip is divided into separate chips according to the functions thereof and the chips are electrically connected to each other. The semiconductor device 200 of the chiplet structure may overcome performance limitation which a single chip may have.

The redistribution layer 300 may be provided between the semiconductor device 200 and the semiconductor package module 100 and electrically connected to the semiconductor device 200 and the semiconductor package module 100.

The redistribution layer 300 may be formed by a redistribution process. The redistribution layer 300 may include a redistribution insulating layer 313 and a plurality of redistribution patterns 310. The redistribution insulating layer 313 may surround the plurality of redistribution patterns 310. In some embodiments, the redistribution layer 300 may include a plurality of redistribution insulating layers 313 that are stacked in a vertical direction. For example, the plurality of redistribution insulating layers 313 may include a first redistribution insulating layer adjacent to the semiconductor package module 100 and a second redistribution insulating layer beneath the first redistribution insulating layer.

The redistribution insulating layer 313 may be formed of, for example, a material film including an organic compound. In some embodiments, the redistribution insulating layer 313 may be formed of a material film including an organic polymer material. In some embodiments, the redistribution insulating layer 313 may be formed of photosensitive polyimide (PSPI). The redistribution insulating layer 313 may include a photosensitive insulating material (a photo imageable dielectric). The redistribution insulating layer 313 may include, for example, a photosensitive polymer. The photosensitive polymer may include, for example, at least one of PSPI, polybenzoxazole, a phenol-based polymer, and a benzocyclobutene-based polymer.

The plurality of redistribution patterns 310 may include a plurality of redistribution line patterns 311 and a plurality of redistribution via patterns 312. The plurality of redistribution patterns 310 may include, for example, a metal, such as Cu, Al, W, Ti, Ta, In, molybdenum (Mo), Mn, Co, Sn, Ni, magnesium (Mg), rhenium (Re), beryllium (Be), gallium (Ga), or Ru, or an alloy of the metal but are not limited thereto.

The plurality of redistribution line patterns 311 may be disposed on at least one surface of the upper surface and the lower surface of the redistribution insulating layer 313. The plurality of redistribution via patterns 312 may be electrically connected to and/or contact portions of the plurality of redistribution line patterns 311 by passing through the redistribution insulating layer 313. The plurality of redistribution via patterns 312 may have a tapered shape extending with a horizontal width gradually decreasing in the direction (the-z direction) receding from the semiconductor package module 100.

In some embodiments, some of the plurality of redistribution line patterns 311 may be integrated with some of the plurality of redistribution via patterns 312. For example, a redistribution line pattern 311 and a redistribution via pattern 312 in contact with the lower surface of the redistribution line pattern 311 may be formed together and integrated, e.g., as one body without a boundary therebetween.

In some embodiments, at least some of the uppermost redistribution line patterns 311 among the plurality of redistribution line patterns 311 may be a plurality of upper conductive pads to which solders 132 are attached. The redistribution via pattern 312 may be electrically connected to and/or contact an upper connection pad 213u of the semiconductor device 200.

The encapsulation material 400 may seal the semiconductor package module 100 on the redistribution layer 300. For example, the encapsulation material 400 may cover/contact the side surface of the sealing material 140 sealing the semiconductor package module 100 on the redistribution layer 300. As shown in FIG. 1, the encapsulation material 400 may not cover the upper surface of the semiconductor package module 100. Accordingly, the upper surface of the semiconductor package module 100 may be exposed from the encapsulation material 400. However, in some embodiments, the encapsulation material 400 may cover/contact the upper surface of the semiconductor package module 100. The encapsulation material 400 may include, for example, an EMC. However, the material of the encapsulation material 400 is not limited to the EMC. For example, the encapsulation material 400 may be a molding layer or an encapsulation layer protecting the semiconductor package module 100 and/or the redistribution layer 300 from chemical, thermal, and mechanical stress.

In an embodiment, each of the encapsulation material 400 and the sealing material 140 may include a resin and an Si filler. For example, each of the encapsulation material 400 and the sealing material 140 may be formed of an insulating material including a resin, such as an epoxy resin. For example, each of the encapsulation material 400 and the sealing material 140 may have a structure in which an Si filler is dispersed in a resin matrix.

According to an embodiment, the Si filler included in the encapsulation material 400 may have a larger size than the Si filler included in the sealing material 140. For example, the average particle diameter of the Si filler included in the encapsulation material 400 may be greater than the average particle diameter of the Si filler included in the sealing material 140.

In addition, the ratio of the Si filler to the resin in the encapsulation material 400 may be greater than the ratio of the Si filler to the resin in the sealing material 140. For example, the volume ratio of the Si filler to the resin in the encapsulation material 400 may be greater than the volume ratio of the Si filler to the resin in the sealing material 140.

As described above, by differently configuring the sizes and volume ratios of the Si fillers in the encapsulation material 400 and the sealing material 140, characteristics suitable for the usages of the encapsulation material 400 and the sealing material 140 may be obtained. For example, the encapsulation material 400 may have a good mechanical strength and thermal conductivity because of the Si filler having a relatively large size and high volume ratio. Accordingly, the protection function and the heat dissipation characteristic of the semiconductor package 1000 against an external shock may be improved.

On the other hand, the sealing material 140 may effectively fill micro spaces between the first to eighth memory chips 110-1 to 110-8 and minimize stress applied to the first to eighth memory chips 110-1 to 110-8 that are stacked, because of the Si filler having a relatively small size and low volume ratio. In addition, by using the small-sized Si filler, the fluidity of the sealing material 140 may be improved, thereby relatively uniformly filling the spaces between the first to eighth memory chips 110-1 to 110-8.

In another embodiment, the encapsulation material 400 may further include an additional filler, such as carbon black or a metal particle, in addition to the Si filler. By including the additional filler, the thermal conductivity of the encapsulation material 400 may be further improved.

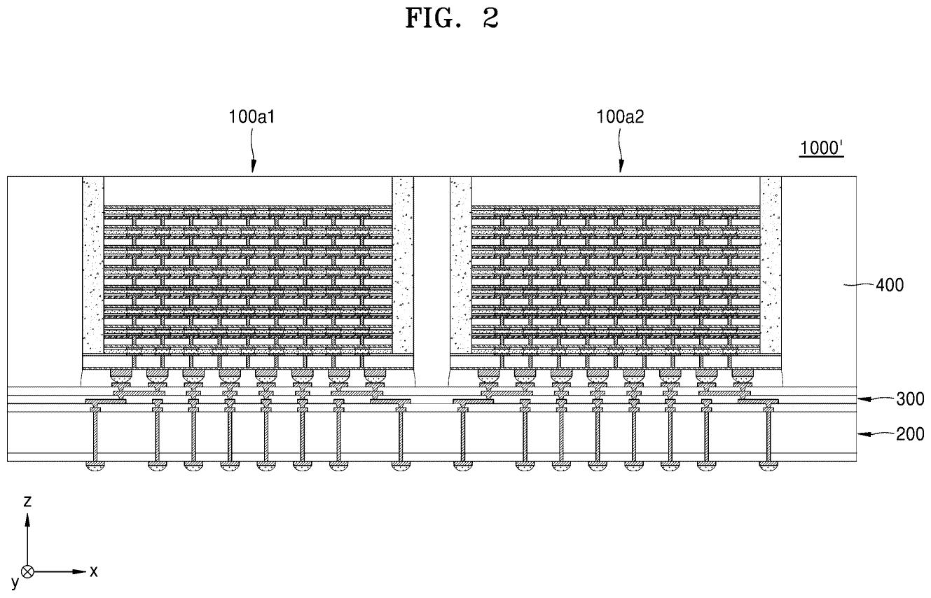

FIG. 2 is a cross-sectional view schematically illustrating a semiconductor package 1000′ according to another embodiment.

Referring to FIG. 2, the semiconductor package 1000′ according to the present embodiment differs from the semiconductor package 1000 of FIG. 1 in that the semiconductor package 1000′ includes a plurality of semiconductor package modules, e.g., first and second semiconductor package modules 100a1 and 100a2. Particularly, the semiconductor package 1000′ of FIG. 2 may include the first and second semiconductor package modules 100a1 and 100a2, the semiconductor device 200, the redistribution layer 300, and the encapsulation material 400. The semiconductor device 200, the redistribution layer 300, and the encapsulation material 400 may be the same as described with respect to the semiconductor package 1000 shown in FIG. 1.

The first and second semiconductor package modules 100a1 and 100a2 may be disposed on the redistribution layer 300 by being spaced apart from each other in a horizontal direction. Each of the first and second semiconductor package modules 100a1 and 100a2 may include the plurality of memory chips 110 that are stacked, e.g., in a vertical direction, the base chip 120, and the sealing material 140.

Each memory chip 110 of each of the first and second semiconductor package modules 100a1 and 100a2 may include the semiconductor substrate 1101, the active layer 111, the through electrode 112, the connection pad 113, the protective layer 114, and the connection terminal 160, as described with reference to FIG. 1. In addition, the adhesive layer 150 may be provided between memory chips 110 adjacent to each other.

The base chip 120 of each of the first and second semiconductor package modules 100a1 and 100a2 may include the semiconductor substrate 1201, the active layer 121, the through electrode 122, the connection pad 123, and the protective layer 124. The first external connection terminal 130 may be electrically connected to and/or contact the wiring layer of the active layer 121 of the base chip 120.

The first and second semiconductor package modules 100a1 and 100a2 may independently operate. For example, while the first semiconductor package module 100a1 is performing a first memory operation, the second semiconductor package modules 100a2 may perform a second memory operation.

The redistribution layer 300 may provide an electrical connection between the first and second semiconductor package modules 100a1 and 100a2 and the semiconductor device 200. The redistribution layer 300 may include independent redistribution patterns corresponding to each of the first and second semiconductor package modules 100a1 and 100a2.

The encapsulation material 400 may seal both the first and second semiconductor package modules 100a1 and 100a2. Particularly, the encapsulation material 400 may be formed on the redistribution layer 300 and fully fill the space between the first and second semiconductor package modules 100a1 and 100a2.

Through this configuration, by integrating a plurality of semiconductor package modules in one semiconductor package, a memory capacity may increase, and an independent operation of each semiconductor package module may be possible, thereby improving the operation efficiency of a system.

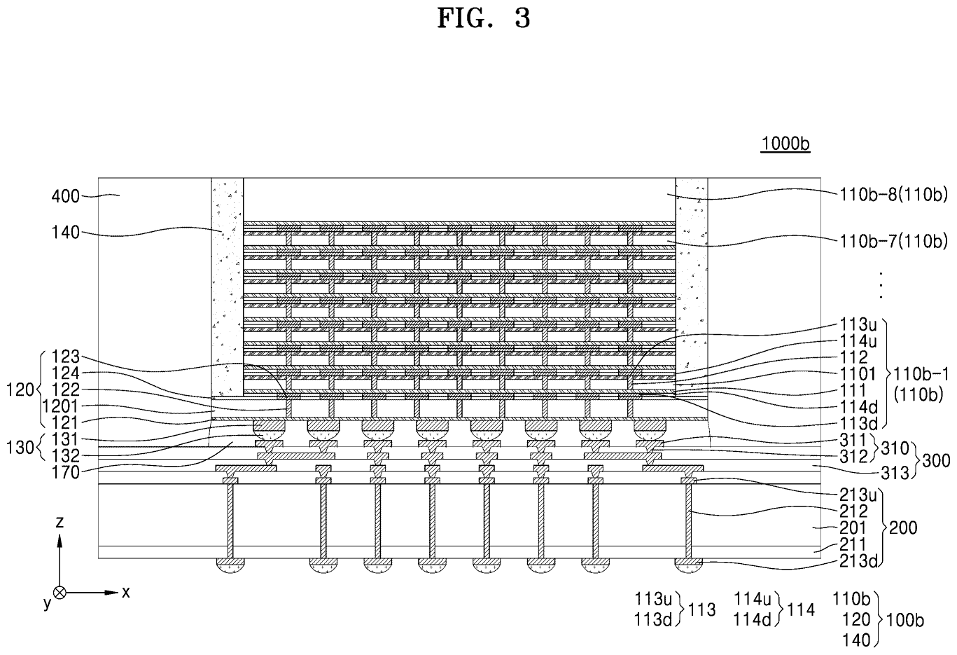

FIG. 3 is a cross-sectional view schematically illustrating a semiconductor package 1000b according to another embodiment.

Referring to FIG. 3, the semiconductor package 1000b according to the present embodiment differs from the semiconductor package 1000 of FIG. 1 in the structure of a semiconductor package module 100b. Particularly, the semiconductor package 1000b shown in FIG. 3 may include the semiconductor package module 100b, the semiconductor device 200, the redistribution layer 300, and the encapsulation material 400. The semiconductor device 200, the redistribution layer 300, and the encapsulation material 400 may be the same as described with respect to the semiconductor package 1000 shown in FIG. 1.

The semiconductor package module 100b of FIG. 3 may differ from the semiconductor package module 100 of FIG. 1 in that memory chips 110b are stacked through hybrid copper bonding (HCB). Particularly, the semiconductor package module 100b of the semiconductor package 1000b of the present embodiment may include the memory chips 110b, the base chip 120, the first external connection terminal 130, and the sealing material 140. The base chip 120, the first external connection terminal 130, and the sealing material 140 are the same as described with respect to the semiconductor package module 100 of the semiconductor package 1000 of FIG. 1. However, because the memory chips 110b are stacked through HCB without the connection terminal 160, there may be no adhesive layer filling between the lowermost memory chip 110b and the base chip 120 and between every pair of adjacent memory chips 110b.

In the semiconductor package 1000b of the present embodiment, the memory chips 110b may be stacked on the base chip 120 or an immediately lower memory chip 110b through HCB. Alternatively, the memory chips 110b may be stacked on the base chip 120 or an immediately lower memory chip 110b through TCB. Herein, HCB may indicate composite bonding of pad-to-pad bonding and insulator-to-insulator bonding. Because pads are commonly formed of Cu, pad-to-pad bonding may be Cu-to-Cu bonding.

In more detail, as described above, the connection pad 123 and the protective layer 124 may be disposed on the upper surface of the base chip 120. In addition, the connection pad 113 and the protective layer 114 may be disposed on the lower surface and the upper surface of each of the memory chips 110b. The connection pad 123 of the base chip 120 may be disposed in a structure of being buried in the protective layer 124, wherein the upper surface of the connection pad 123 is exposed from the protective layer 124. In addition, the connection pad 113 of the memory chip 110b may be disposed in a structure of being buried in the protective layer 114, wherein the upper surface or the lower surface of the connection pad 113 is exposed from the protective layer 114. Each of the protective layers 114 and 124 may include, for example, an insulating film, such as SiO₂ or silicon nitride (SiN).

The connection pad 123 of the base chip 120 may be coupled to the lower connection pad 113d of a first memory chip 110b-1, and the protective layer 124 of the base chip 120 may be coupled to the lower protective layer 114d of the first memory chip 110b-1, thereby forming HCB between the base chip 120 and the first memory chip 110b-1. In addition, in the memory chips 110b, between two adjacent memory chips 110b, the upper connection pad 113u and the upper protective layer 114u on the upper surface of the lower memory chip 110b may be respectively coupled to the lower connection pad 113d and the lower protective layer 114d on the lower surface of the upper memory chip 110b, thereby forming HCB.

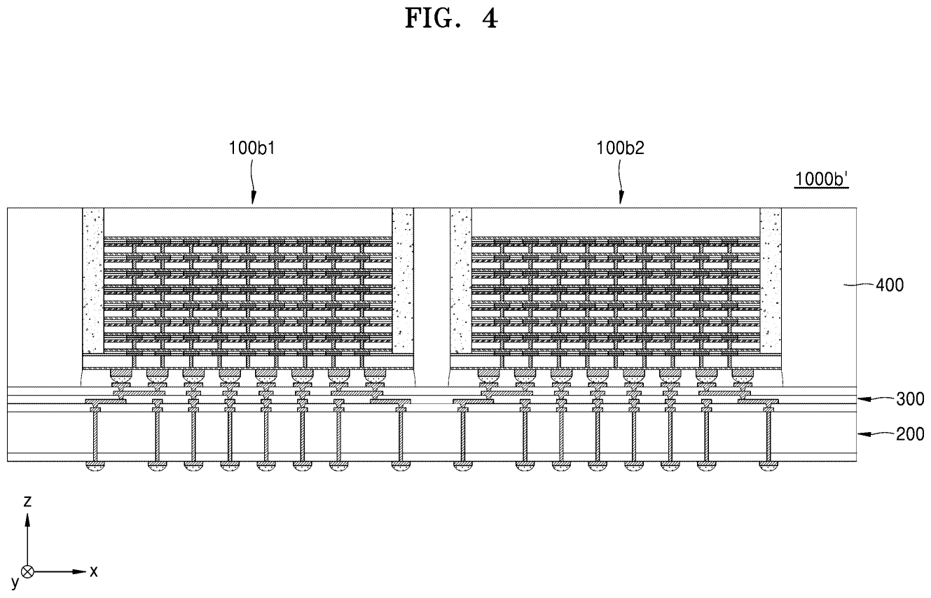

FIG. 4 is a cross-sectional view schematically illustrating a semiconductor package 1000b′ according to another embodiment.

Referring to FIG. 4, the semiconductor package 1000b′ according to the present embodiment differs from the semiconductor package 1000b of FIG. 3 in that the semiconductor package 1000b′ includes a plurality of semiconductor package modules 100b1 and 100b2. Particularly, the semiconductor package 1000b′ shown in FIG. 4 may include the plurality of semiconductor package modules 100b1 and 100b2, the semiconductor device 200, the redistribution layer 300, and the encapsulation material 400. The semiconductor device 200, the redistribution layer 300, and the encapsulation material 400 may be the same as described with respect to the semiconductor package 1000 shown in FIG. 1. Each of the plurality of semiconductor package modules 100b1 and 100b2 is the same as described with respect to the semiconductor package module 100b shown in FIG. 3.

The present embodiment differs from the embodiment of FIG. 3 in that the plurality of semiconductor package modules 100b1 and 100b2 of the semiconductor package 1000b′ are arranged in the horizontal direction. Particularly, each of the plurality of semiconductor package modules 100b1 and 100b2 may include memory chips 110b stacked through HCB.

The plurality of semiconductor package modules 100b1 and 100b2 may be disposed on the redistribution layer 300 by being spaced apart from each other in the horizontal direction. The plurality of semiconductor package modules 100b1 and 100b2 may be electrically connected to the semiconductor device 200 via the redistribution layer 300. The redistribution layer 300 may include independent redistribution patterns corresponding to each semiconductor package module, and each semiconductor package module may independently operate.

The encapsulation material 400 may be formed on the redistribution layer 300 and seal the plurality of semiconductor package modules 100b1 and 100b2. For example, the encapsulation material 400 may fully fill the space between the plurality of semiconductor package modules 100b1 and 100b2.

Through this configuration, the semiconductor package 1000b′ according to the present embodiment may employ HCB to reduce a package height and may horizontally arrange the plurality of semiconductor package modules 100b1 and 100b2 to increase a memory capacity. In addition, each semiconductor package module may independently operate, and the operation efficiency of a system may be improved.

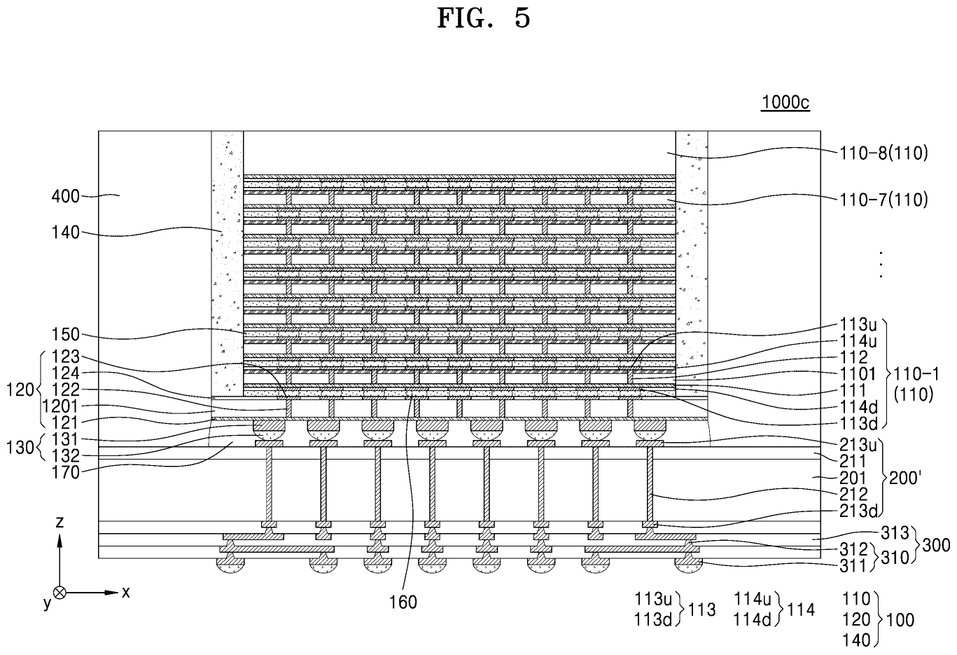

FIG. 5 is a cross-sectional view schematically illustrating a semiconductor package 1000c according to another embodiment.

Referring to FIG. 5, the semiconductor package 1000c according to the present embodiment differs from the semiconductor package 1000 of FIG. 1 in the arrangement of a semiconductor device 200′ and the redistribution layer 300. Particularly, the semiconductor package 1000c shown in FIG. 5 may include the semiconductor package module 100, the semiconductor device 200′, the redistribution layer 300, and the encapsulation material 400. The semiconductor package module 100 and the encapsulation material 400 are the same as described with respect to the semiconductor package module 100 and the encapsulation material 400 of the semiconductor package 1000 of FIG. 1.

The present embodiment differs from the embodiment of FIG. 1 in that the semiconductor device 200′ is disposed between the semiconductor package module 100 and the redistribution layer 300. Particularly, the semiconductor device 200′ may include the active layer 211 formed on the upper surface of the semiconductor substrate 201, and the redistribution layer 300 may be formed on the lower surface of the semiconductor substrate 201.

In this structure, the active layer 211 of the semiconductor device 200′ may be disposed to face the semiconductor package module 100 such that the electrical connection path between the semiconductor package module 100 and the semiconductor device 200′ is minimized. This may improve a signal transfer characteristic and reduce an electrical loss.

The semiconductor package module 100 may be disposed on the semiconductor device 200′. First external connection terminals 130 of the semiconductor package module 100 may be electrically connected to upper connection pads 213u of the semiconductor device 200′.

As explained with respect to FIG. 1, the semiconductor package module 100 of the present embodiment may include the plurality of memory chips 110 that are stacked, e.g., in the vertical direction, the base chip 120, the adhesive layer 150, and the sealing material 140. The plurality of memory chips 110 may be electrically connected to each other via the connection terminal 160, and the adhesive layer 150 may be provided between every pair of adjacent memory chips 110.

The redistribution layer 300 may be formed on the lower surface of the semiconductor device 200′ and provide an electrical connection between the semiconductor device 200′ and the outside. The encapsulation material 400 may be formed on the semiconductor device 200′ and seal the semiconductor package module 100.

The structure of the present embodiment may optimize the electrical connection path between the semiconductor package module 100 and the semiconductor device 200′, thereby being particularly useful for a semiconductor package requiring a high speed operation. In addition, through a structure in which the active layer 211 of the semiconductor device 200′ directly faces the semiconductor package module 100, the overall signal transfer efficiency of the semiconductor package 1000c may be improved.

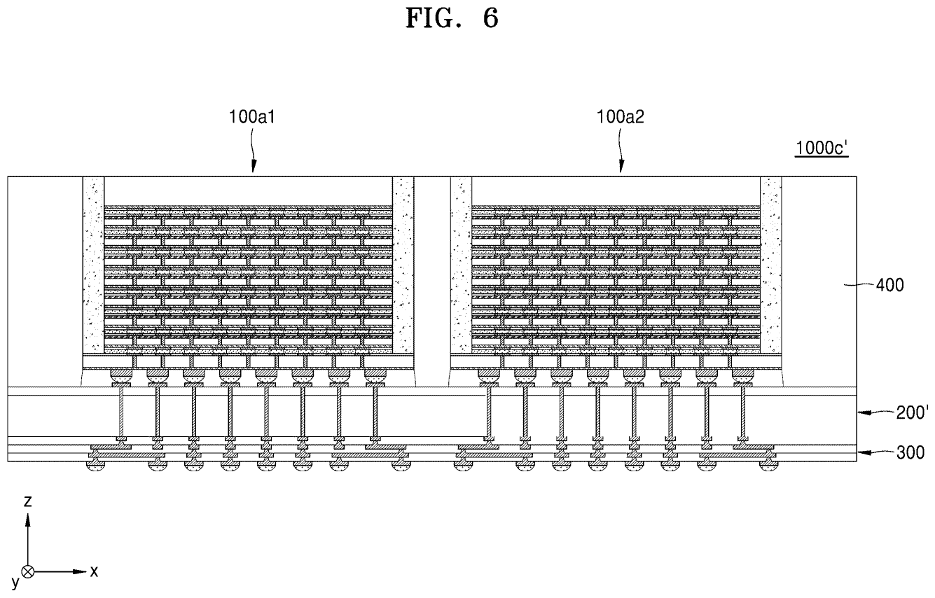

FIG. 6 is a cross-sectional view schematically illustrating a semiconductor package 1000c′ according to another embodiment.

Referring to FIG. 6, the semiconductor package 1000c′ according to the present embodiment differs from the semiconductor package 1000c of FIG. 5 in that the semiconductor package 1000c′ includes a plurality of semiconductor package modules 100a1 and 100a2. Particularly, the semiconductor package 1000c′ of FIG. 6 may include the plurality of semiconductor package modules 100a1 and 100a2, the semiconductor device 200′, the redistribution layer 300, and the encapsulation material 400. The semiconductor device 200′, the redistribution layer 300, and the encapsulation material 400 may be the same as described with respect to the semiconductor package 1000c shown in FIG. 5.

The plurality of semiconductor package modules 100a1 and 100a2 may be disposed on the semiconductor device 200′ by being spaced apart from each other in the horizontal direction. Each of the plurality of semiconductor package modules 100a1 and 100a2 may include the plurality of memory chips 110 that are stacked in the vertical direction, the base chip 120, and the sealing material 140.

Each memory chip 110 of each of the plurality of semiconductor package modules 100a1 and 100a2 may include the semiconductor substrate 1101, the active layer 111, the through electrode 112, the connection pad 113, the protective layer 114, and the connection terminal 160, as described with reference to FIG. 1. In addition, the adhesive layer 150 may be provided between memory chips 110 adjacent to each other.

The base chip 120 of each of the plurality of semiconductor package modules 100a1 and 100a2 may include the semiconductor substrate 1201, the active layer 121, the through electrode 122, the connection pad 123, and the protective layer 124. The first external connection terminal 130 may be electrically connected to and/or contact the wiring layer of the active layer 121 of the base chip 120.

The plurality of semiconductor package modules 100a1 and 100a2 may independently operate. For example, while the first semiconductor package module 100a1 is performing a first memory operation, the second semiconductor package modules 100a2 may perform a second memory operation.

The encapsulation material 400 may simultaneously seal the plurality of semiconductor package modules 100a1 and 100a2. Particularly, the encapsulation material 400 may be formed on the semiconductor device 200′ and fully fill the space between the plurality of semiconductor package modules 100a1 and 100a2.

Through this configuration, by integrating a plurality of semiconductor package modules in one semiconductor package, a memory capacity may increase, and an independent operation of each semiconductor package module may be possible, thereby improving the operation efficiency of a system.

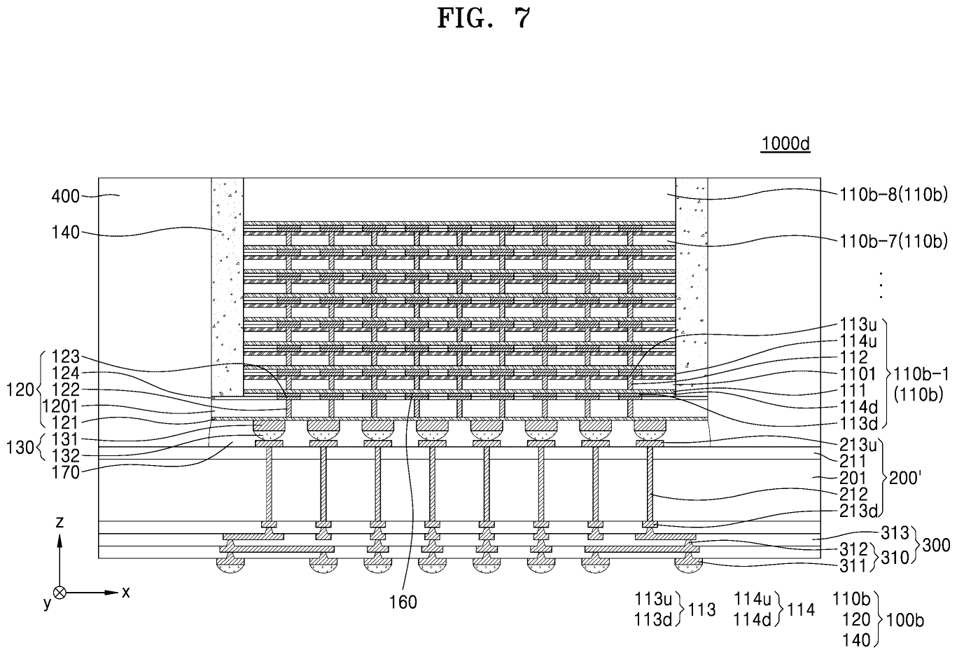

FIG. 7 is a cross-sectional view schematically illustrating a semiconductor package 1000d according to another embodiment.

Referring to FIG. 7, the semiconductor package 1000d according to the present embodiment differs from the semiconductor package 1000c of FIG. 5 in the structure of the semiconductor package module 100b. Particularly, the semiconductor package 1000d shown in FIG. 7 may include the semiconductor package module 100b, the semiconductor device 200′, the redistribution layer 300, and the encapsulation material 400. The semiconductor device 200′, the redistribution layer 300, and the encapsulation material 400 may be the same as described with respect to the semiconductor package 1000c shown in FIG. 5.

The semiconductor package module 100b of FIG. 7 may differ from the semiconductor package module 100 of FIG. 5 in that the memory chips 110b are stacked through HCB. Particularly, the semiconductor package module 100b of the semiconductor package 1000d of the present embodiment may include the memory chips 110b, the base chip 120, the first external connection terminal 130, and the sealing material 140. The base chip 120, the first external connection terminal 130, and the sealing material 140 are the same as described with respect to the semiconductor package module 100 of the semiconductor package 1000c of FIG. 5. However, because the memory chips 110b are stacked through HCB without the connection terminal 160, there may be no adhesive layer filling between the lowermost memory chip 110b and the base chip 120 and between every pair of adjacent memory chips 110b.

In the semiconductor package 1000d of the present embodiment, the memory chips 110b may be stacked on the base chip 120 or an immediately lower memory chip 110b through HCB. Alternatively, the memory chips 110b may be stacked on the base chip 120 or an immediately lower memory chip 110b through TCB.

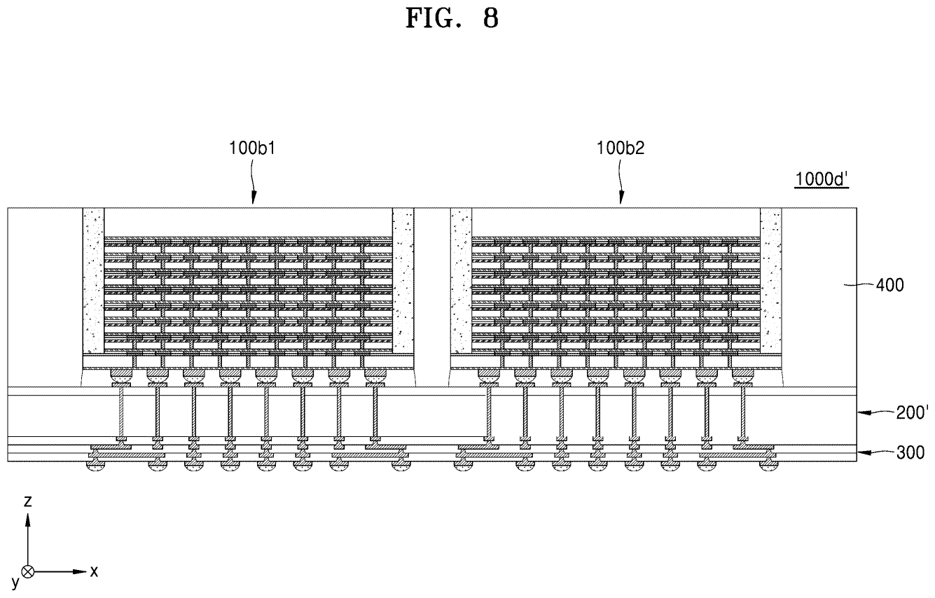

FIG. 8 is a cross-sectional view schematically illustrating a semiconductor package 1000d′ according to another embodiment.

Referring to FIG. 8, the semiconductor package 1000d′ according to the present embodiment differs from the semiconductor package 1000d of FIG. 7 in that the semiconductor package 1000d′ includes the plurality of semiconductor package modules 100b1 and 100b2. Particularly, the semiconductor package 1000d′ shown in FIG. 8 may include the plurality of semiconductor package modules 100b1 and 100b2, the semiconductor device 200′, the redistribution layer 300, and the encapsulation material 400. The semiconductor device 200′, the redistribution layer 300, and the encapsulation material 400 may be the same as described with respect to the semiconductor package 1000c shown in FIG. 5. Each of the plurality of semiconductor package modules 100b1 and 100b2 is the same as described with respect to the semiconductor package module 100b shown in FIG. 7.

The present embodiment differs from the embodiment of FIG. 7 in that the plurality of semiconductor package modules 100b1 and 100b2 of the semiconductor package 1000d′ are arranged in the horizontal direction. Particularly, each of the plurality of semiconductor package modules 100b1 and 100b2 may include memory chips 110b stacked through HCB.

The plurality of semiconductor package modules 100b1 and 100b2 may be disposed on the semiconductor device 200′ by being spaced apart from each other in the horizontal direction. The plurality of semiconductor package modules 100b1 and 100b2 may be electrically connected to the upper connection pad 213u of the semiconductor device 200′.

The encapsulation material 400 may be formed on the semiconductor device 200′ and seal the plurality of semiconductor package modules 100b1 and 100b2. Particularly, the encapsulation material 400 may fully fill the space between the plurality of semiconductor package modules 100b1 and 100b2.

Through this configuration, the semiconductor package 1000d′ according to the present embodiment may employ HCB to reduce a package height and may horizontally arrange the plurality of semiconductor package modules 100b1 and 100b2 to increase a memory capacity. In addition, each semiconductor package module may independently operate, and the operation efficiency of a system may be improved.

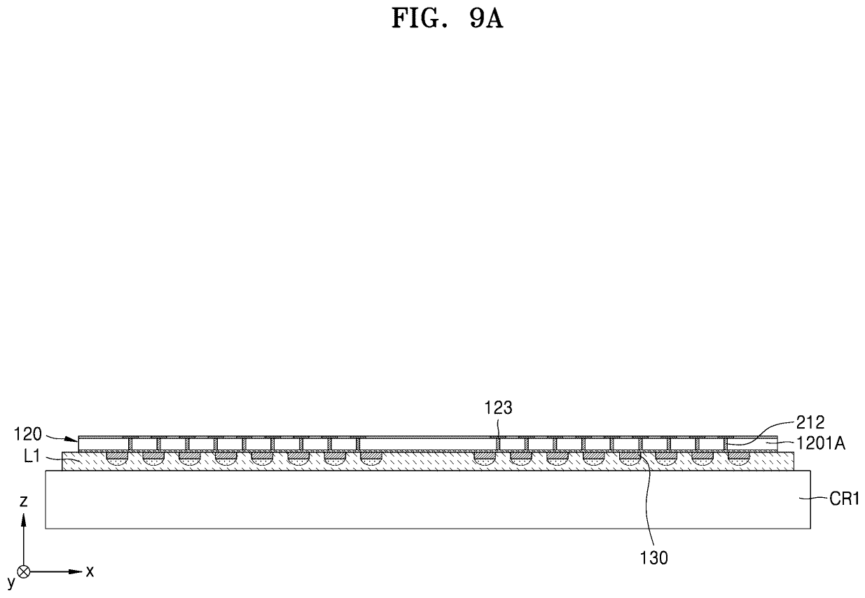

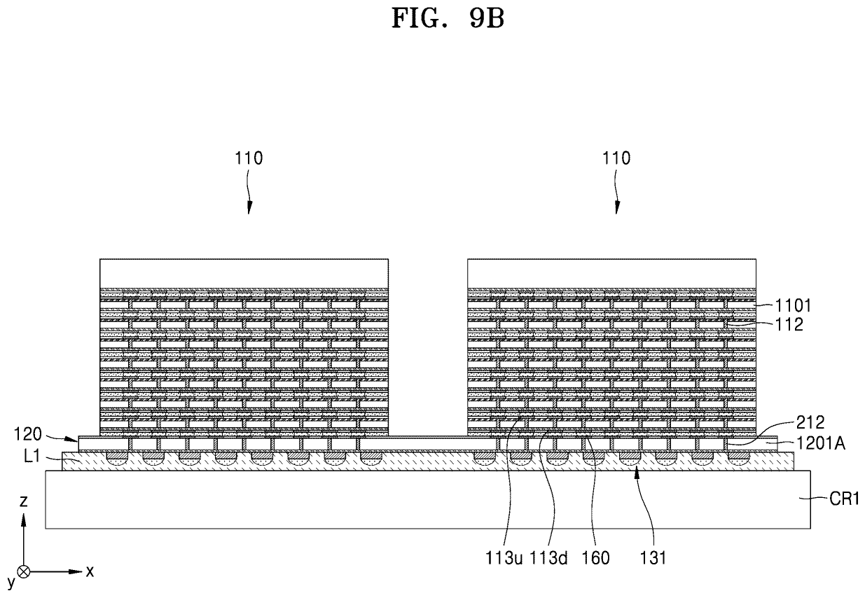

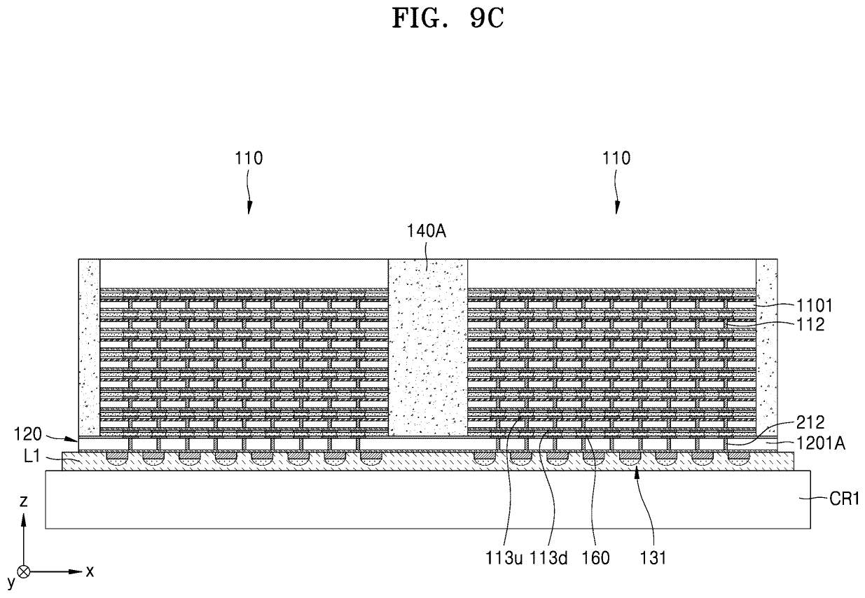

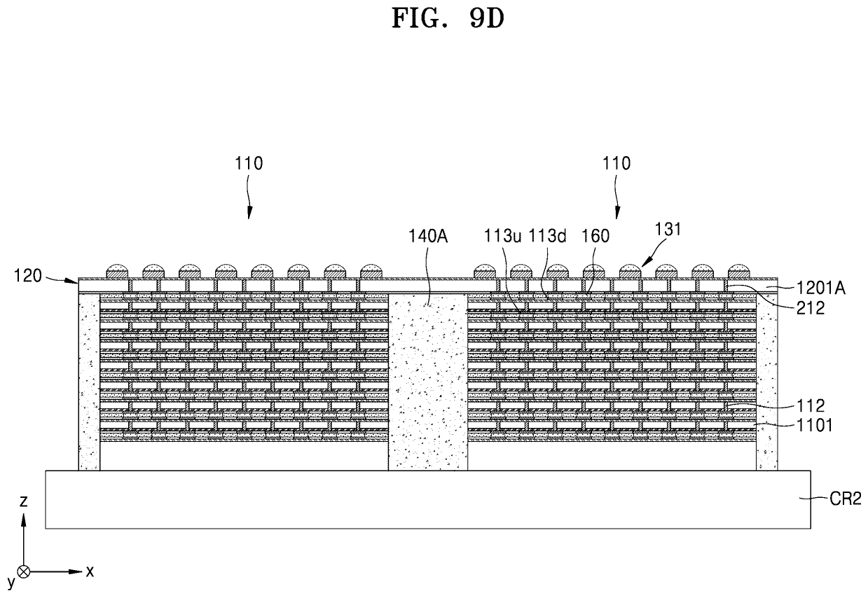

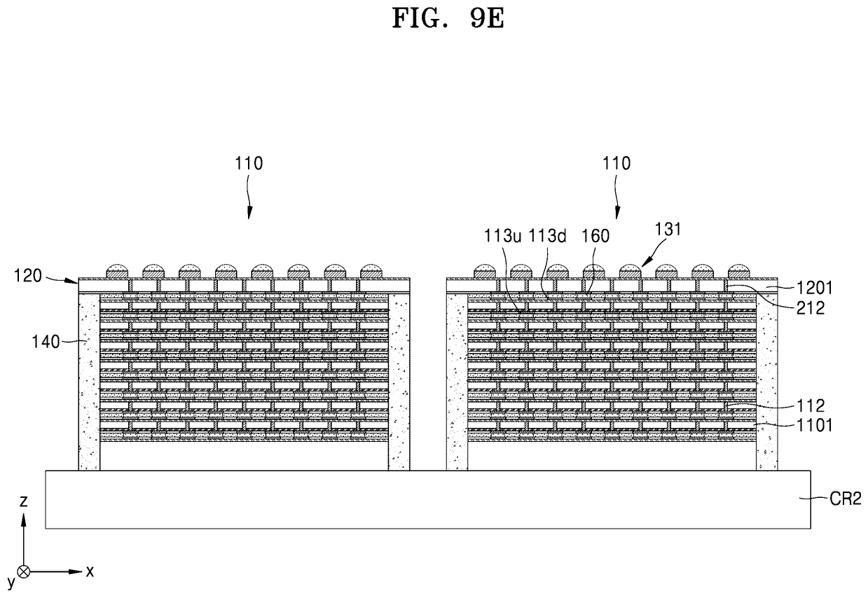

FIGS. 9A to 9E are cross-sectional views sequentially illustrating a method of manufacturing a semiconductor package module, according to an embodiment. Features of components not described below may be the same as the description made above.

Referring to FIG. 9A, a semiconductor substrate 1201A may be disposed on a first carrier CR1. For example, an active layer 121, connection pads 123, and a protective layer 124 may be formed on the semiconductor substrate 1201A, and through electrodes 122 may be formed in the semiconductor substrate 1201A. The semiconductor substrate 1201A may indicate/be a portion of a wafer including a plurality of base chips 120 before individualization are formed. The semiconductor substrate 1201A may be attached to the first carrier CR1 by a first attachment layer L1.

The semiconductor substrate 1201A may be disposed on the first carrier CR1 such that the first external connection terminal 130 faces the first carrier CR1. The first attachment layer L1 may cover the first external connection terminal 130. A BS process may be performed on the upper surface of the semiconductor substrate 1201A to make the semiconductor substrate 1201A thin. The BS process may include a grinding process or a chemical mechanical polishing process. Thereafter, the connection pad 123 described above may be formed on the upper surface of the semiconductor substrate 1201A.

Referring to FIG. 9B, at least one memory chip 110 may be mounted on the semiconductor substrate 1201A. For example, one or more memory chips 110 may be mounted on each portion of the semiconductor substrate 1201A which corresponds to a base chip 120. The memory chip 110 may be a semiconductor chip fabricated with a separate wafer and individualized.

Connection terminals 160 may be provided between the memory chips 110, e.g., between one memory chip 110 and another adjacent memory chip 110. Each of connection terminals 160 may be provided between a lower connection pad 113d on the lower surface of one memory chip 110 and an upper connection pad 113u on the upper surface of another adjacent memory chip 110 positioned thereunder. An inter-chip adhesive layer 150 may be provided between the memory chips 110, e.g., between one memory chip 110 and another adjacent memory chip 110. Mounting the plurality of memory chips 110 on the semiconductor substrate 1201A may be performed by a TCB process.

In some embodiments, for example, in a process of manufacturing the semiconductor package 1000b of FIG. 3, mounting the memory chips 110b on the semiconductor substrate 1201A may be performed by a direct bonding process including HCB described above.

Referring to FIG. 9C, a sealing material 140A may be formed on the semiconductor substrate 1201A and cover the sidewalls of the plurality of memory chips 110. The sealing material 140A may be formed between the plurality of memory chips 110 disposed as a plurality of stacks on the semiconductor substrate 1201A. The sealing material 140A may be formed at a wafer level.

The sealing material 140A may be formed to cover, for example, the upper surface of the uppermost memory chip, e.g., the eighth memory chip 110-8 (see FIG. 1). The sealing material 140A covering the upper surface of the uppermost memory chip 110-8 (see FIG. 1) may be removed through a grinding process or a chemical mechanical polishing process. Therefore, the upper surface of the sealing material 140A may be coplanar with the upper surface of the uppermost memory chip 110-8 (see FIG. 1).

Referring to FIG. 9D, the first carrier CR1 (see FIG. 9C) and the first attachment layer L1 (see FIG. 9C) may be removed, thereby exposing one surface of the semiconductor substrate 1201A. The process result of FIG. 9C may be disposed on a second carrier CR2. An electrical die sorting (EDS) test may be performed on the process result of FIG. 9C disposed on the second carrier CR2. Through the EDS test, good products and bad products may be preemptively distinguished to selectively perform a process after individualization to be performed with reference to FIG. 9E.

Referring to FIG. 9E, the process result of FIG. 9D may be individualized to form a plurality of semiconductor package modules each including the plurality of memory chips 110, the base chip 120, and the sealing material 140 described in the embodiments above. For example, sawing may be performed on the process result of FIG. 9D along a scribe lane region, thereby performing individualization. Because of the individualization for forming the plurality of semiconductor package modules, the sidewall of the sealing material 140 and the sidewall of the base chip 120 may be aligned in the vertical direction, e.g., coplanar.

After manufacturing the plurality of semiconductor package modules, the plurality of semiconductor package modules may be transported to perform a post-process thereon. For example, the plurality of semiconductor package modules may be accommodated on a tape having pockets each produced to fit the semiconductor package module, and the tape may be rolled around a reel, stored, and then transported. Alternatively, the plurality of semiconductor package modules may be loaded on a semiconductor package transportation tray, then packaged, and transported to a place where a post-process is to be performed. The inventive concept is not limited by the method of transportation of the plurality of semiconductor package modules.

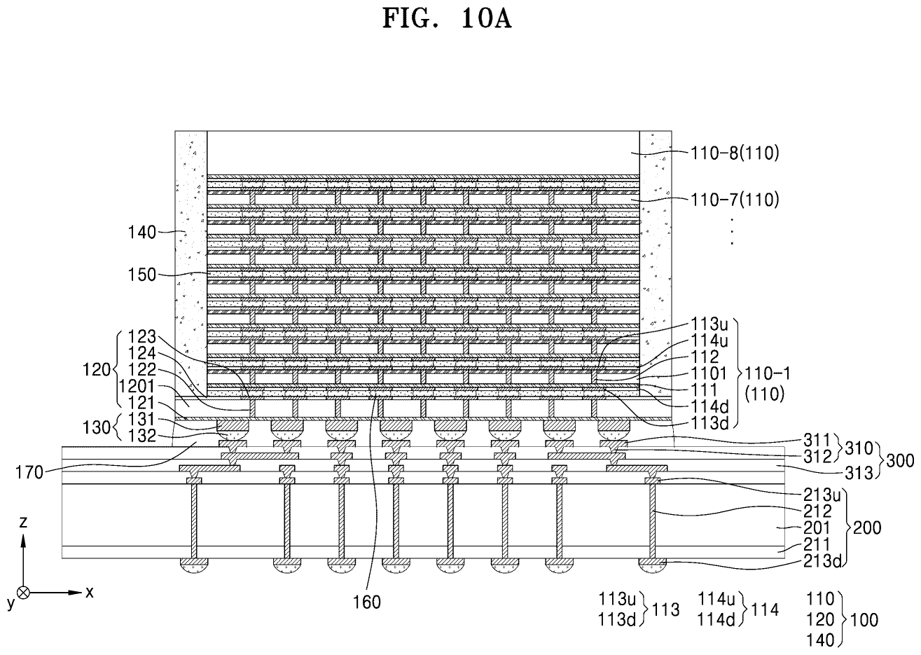

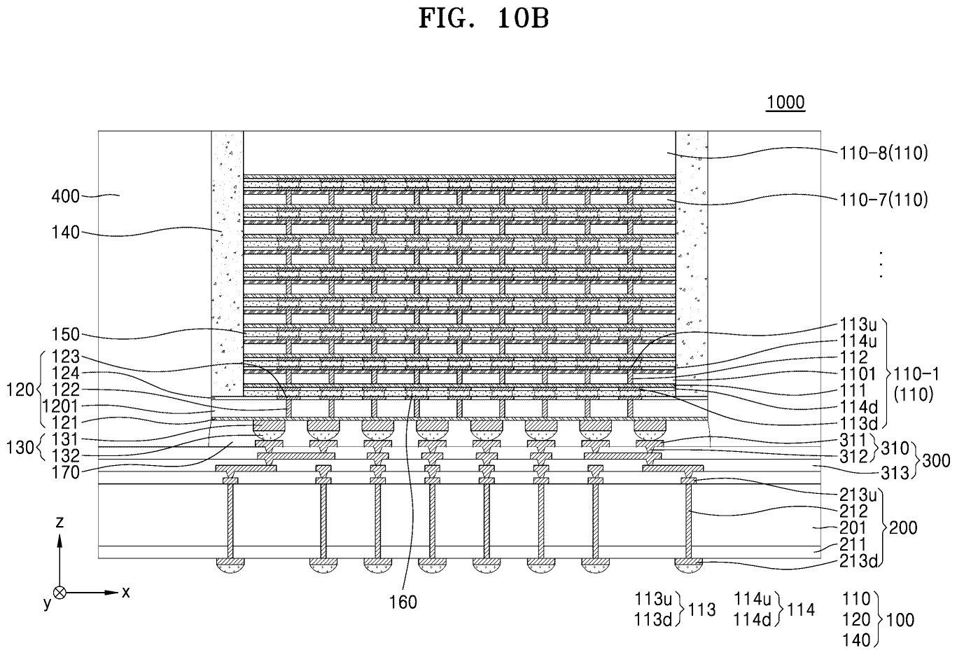

FIGS. 10A and 10B are cross-sectional views sequentially illustrating a method of manufacturing the semiconductor package 1000, according to an embodiment. Features of components/methods not described below may be the same as the description made above.

Referring to FIG. 10A, the semiconductor package module 100 may be mounted on the redistribution layer 300 formed on the semiconductor device 200. For example, on a wafer having a plurality of semiconductor devices 200, the semiconductor package module 100 may be mounted on the redistribution layer 300 formed on the upper surface of the semiconductor device 200. For example, the semiconductor package module 100 may be provided on the wafer having the plurality of semiconductor devices 200 by a wafer on chip (WoC) process.

After disposing the semiconductor package module 100 on the redistribution layer 300, a TCB process may be performed. By the TCB process, the pillar 131 of the base chip 120 may be electrically connected by the solder 132 to a redistribution pattern 310 of the redistribution layer 300. Thereafter, the under-fill layer 170 surrounding the first external connection terminal 130 may be provided between the base chip 120 and the redistribution layer 300.

Referring to FIG. 10B, the encapsulation material 400 may be formed on the semiconductor device 200 and cover the semiconductor package module 100. For example, on the wafer having the plurality of semiconductor devices 200 each having the semiconductor package module 100 disposed thereon, the encapsulation material 400 may be formed to surround semiconductor package modules 100.

The encapsulation material 400 covering the upper surface of the uppermost memory chip 110-8 may be removed through a grinding process or a chemical mechanical polishing process. Therefore, the upper surface of the sealing material 140, the upper surface of the encapsulation material 400, and the upper surface of the uppermost memory chip 110-8 may be coplanar with each other.

Thereafter, individualization for cutting the wafer including the encapsulation material 400 and the semiconductor device 200 may be performed. In some embodiments, the individualization may be achieved by sawing the wafer including the encapsulation material 400 and the semiconductor device 200, and accordingly, the side surface of the encapsulation material 400 and the side surface of the semiconductor device 200 may be aligned in the vertical direction, e.g., coplanar. Through this process, the semiconductor package 1000, as shown in FIG. 1, may be manufactured.

Even though different figures illustrate variations of exemplary embodiments and different embodiments disclose different features from each other, these figures and embodiments are not necessarily intended to be mutually exclusive from each other. Rather, features depicted in different figures and/or described above in different embodiments can be combined with other features from other figures/embodiments to result in additional variations of embodiments, when taking the figures and related descriptions of embodiments as a whole into consideration. For example, components and/or features of different embodiments described above can be combined with components and/or features of other embodiments interchangeably or additionally to form additional embodiments unless the context clearly indicates otherwise, and the present disclosure includes the additional embodiments.

While the inventive concept has been particularly shown and described with reference to embodiments thereof, it will be understood that various changes in form and details may be made therein without departing from the spirit and scope of the following claims.

What is claimed is:

1. A semiconductor package comprising:
a semiconductor package module;
a semiconductor device provided below the semiconductor package module;
a redistribution layer between the semiconductor package module and the semiconductor device; and
an encapsulation material surrounding the semiconductor package module, on the redistribution layer,
wherein the semiconductor package module comprises:
a base chip;
a plurality of memory chips disposed on the base chip; and
a sealing material sealing the plurality of memory chips on the base chip,
wherein each of the plurality of memory chips comprises a first semiconductor substrate, a first active layer on a lower surface of the first semiconductor substrate, and a first through electrode extending through the first semiconductor substrate, and
wherein the base chip comprises a second semiconductor substrate, a second active layer on a lower surface of the second semiconductor substrate, and a second through electrode extending through the second semiconductor substrate,
wherein the semiconductor device comprises a third semiconductor substrate, a third active layer on a lower surface of the third semiconductor substrate, and a third through electrode extending through the third semiconductor substrate, and
wherein the redistribution layer is formed on an upper surface of the third semiconductor substrate.

2. The semiconductor package of claim 1, wherein a plan view area of the base chip is larger than a plan view area of the plurality of memory chips, and a plan view area of the semiconductor device is larger than the plan view area of the base chip.

3. The semiconductor package of claim 1, wherein a plurality of semiconductor package modules are disposed above the semiconductor device.

4. The semiconductor package of claim 1, wherein each of the plurality of memory chips is stacked on the base chip or an immediately lower memory chip through a connection terminal.

5. The semiconductor package of claim 1, wherein each of the plurality of memory chips is stacked on the base chip or an immediately lower memory chip through hybrid copper bonding (HCB).

6. The semiconductor package of claim 1, wherein each of the encapsulation material and the sealing material comprises a resin and a silicon filler.

7. The semiconductor package of claim 6, wherein the silicon filler of the encapsulation material has a larger size than the silicon filler of the sealing material.

8. The semiconductor package of claim 6, wherein a ratio of the silicon filler to the resin in the encapsulation material is greater than a ratio of the silicon filler to the resin in the sealing material.

9. The semiconductor package of claim 1, wherein an uppermost memory chip among the plurality of memory chips does not have a through electrode.

10. A semiconductor package comprising:
a semiconductor package module;
a semiconductor device provided beneath the semiconductor package module;
a redistribution layer provided beneath the semiconductor device; and
an encapsulation material surrounding the semiconductor package module, on the semiconductor device,
wherein the semiconductor package module comprises:
a base chip;
a plurality of memory chips disposed on the base chip; and
a sealing material sealing the plurality of memory chips on the base chip,
wherein each of the plurality of memory chips comprises a first semiconductor substrate, a first active layer on a lower surface of the first semiconductor substrate, and a first through electrode extending through the first semiconductor substrate,
wherein the base chip comprises a second semiconductor substrate, a second active layer on a lower surface of the second semiconductor substrate, and a second through electrode extending through the second semiconductor substrate,
wherein the semiconductor device comprises a third semiconductor substrate, a third active layer on an upper surface of the third semiconductor substrate, and a third through electrode extending through the third semiconductor substrate, and
wherein the redistribution layer is formed on a lower surface of the third semiconductor substrate.

11. The semiconductor package of claim 10, wherein a plan view area of the base chip is larger than a plan view area of the plurality of memory chips, and a plan view area of the semiconductor device is larger than the plan view area of the base chip.

12. The semiconductor package of claim 10, wherein a plurality of semiconductor package modules are disposed on the semiconductor device.

13. The semiconductor package of claim 10, wherein each of the plurality of memory chips is stacked on the base chip or an immediately lower memory chip through a connection terminal.

14. The semiconductor package of claim 10, wherein each of the plurality of memory chips is stacked on the base chip or an immediately lower memory chip through hybrid copper bonding (HCB).

15. The semiconductor package of claim 10, wherein each of the encapsulation material and the sealing material comprises a resin and a silicon filler.

16. The semiconductor package of claim 15, wherein the silicon filler of the encapsulation material has a larger size than the silicon filler of the sealing material.

17. The semiconductor package of claim 15, wherein a ratio of the silicon filler to the resin in the encapsulation material is greater than a ratio of the silicon filler to the resin in the sealing material.

18. The semiconductor package of claim 10, wherein an uppermost memory chip among the plurality of memory chips does not have a through electrode.

19. A method of manufacturing a semiconductor package, the method comprising:
forming a plurality of base chips on a first wafer;
stacking a plurality of memory chips on each of the plurality of base chips provided on the first wafer;
forming a sealing material surrounding the plurality of memory chips, on the first wafer;
individualizing the first wafer on which the plurality of memory chips are stacked, into a plurality of semiconductor package modules;
mounting a semiconductor package module on a semiconductor device; and
forming an encapsulation material surrounding the semiconductor package module, on the semiconductor device,
wherein the plurality of memory chips, the base chip, and the semiconductor device have a plurality of first through electrodes, a plurality of second through electrodes, and a plurality of third through electrodes, respectively.

20. The method of claim 19, wherein the stacking of the plurality of memory chips comprises mounting the plurality of memory chips on the first wafer by a thermal compression bonding process, and the mounting of the semiconductor package module comprises mounting the semiconductor package module on the semiconductor device by thermal compression bonding.
